(19) United States
(12) Patent Application Publication
(10) Pub. No.: US 2012/0293968 A1
(43) Pub. Date: Nov. 22, 2012

(54) RETAINER FOR ADJACENT-ORIENTED CARDS

(76) Inventor: James D. Hensley, Rocklin, CA (US)

(21) Appl. No.: 13/108,583

(22) Filed: May 16, 2011

(51) Int. Cl. H05K 7/00

(52) U.S. Cl. 361/748

(57) ABSTRACT

Fasteners and fastening systems for holding an electronic card on a bulkhead are disclosed. An example of a fastener includes a pin on a first side of the bulkhead. The fastener also includes a bracket to hold a portion of the electronic card on the pin of the bulkhead. The fastener also includes a connector to hold the bracket on a second side of the bulkhead, the first side of the bulkhead substantially perpendicular to the second side of the bulkhead.

### BACKGROUND

Electronic cards such as Peripheral Component Interconnect (PCI) cards are widely used in electronics such as computing systems. The PCI card is a bus architecture used to connect peripheral devices (e.g., communications, display, sound, and other devices) to the computing system. Initially used in personal desktop computers, PCI cards are now also being used in large computing environments, such as “rack” systems. Rack systems are typically used in network environments and enable the co-location of computing devices such as servers which serve multiple client computing devices. The infrastructure can be provided at low-cost and offers the additional benefit of utilizing shared space, power and cooling and other system components in a large-scale computing environment.

The common manner for securing PCI cards usually involves screws. This requires a screwdriver, which can be difficult if not impossible to reach into some areas within the enclosure. This is particularly acute as more and more components are installed in the enclosure. When this happens, the space in the enclosure is occupied by a mass of electronic components and even adjacent PCI cards so that there is not enough space for operating the screwdriver.

### BRIEF DESCRIPTION OF THE DRAWINGS

FIG. 1 is a perspective view of a portion of an electronic device showing a plurality of electronic cards arranged therein.

FIG. 2a is an exploded perspective view of an example fastening system for connecting an electronic card to a bulkhead.

FIG. 2b is a perspective view of the fastening system in FIG. 2a showing the electronic card after being connected to the bulkhead.

FIGS. 3a-b are perspective views of another example fastening system for connecting an electronic card to a bulkhead.

FIGS. 4a-b are perspective views of example brackets for use with a fastening system for connecting an electronic card to a bulkhead.

FIG. 5 is a perspective view of another example fastening system for connecting a plurality of electronic cards to a bulkhead.

### DETAILED DESCRIPTION

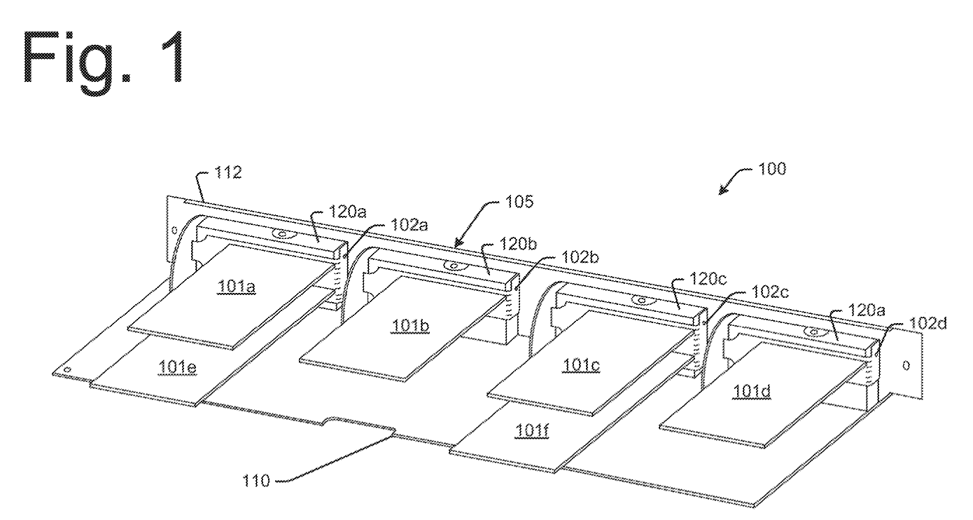

As mentioned above, securing electronic cards (e.g., PCI cards) in an enclosure is often accomplished using a screwdriver, which can be difficult if not impossible to reach, into and operate in some areas within the enclosure. This problem is particularly acute in configurations such as the one shown in FIG. 1, where the electronic cards are arranged horizontally and directly adjacent one another. A fastener and fastening system is described herein which may be used in this and other environments as a retainer, e.g., for adjacent-oriented cards.

FIG. 1 is a perspective view of a portion of an electronic device 100 showing a plurality of electronic cards 101a-d arranged therein. Referring to FIG. 1, an example of a computer enclosure 105 is shown which may be implemented in a rack environment. The computer enclosure 105 includes a housing with a floor 110 and a face 112. Although only electronic cards 101a-d are shown in FIG. 1, more or fewer electronic cards 101a-d may be provided, as may other electronic components (not shown).

The computer enclosure 105 also includes a plurality of card bulkheads 120a-d mounted to the floor 110. The bulkheads 120a-d are used for physically mounting the electronic cards 101a-d. The electronic cards 101a-d may be electronically connected using receptacles, wiring, or other electronic connections.

In a rack environment, it may be particularly desirable to configure the electronic cards 101a-d in a horizontal arrangement in order to fit more readily within standard rack heights (e.g., 1U, 2U, etc.). However, when a plurality of electronic cards 101a-d are inserted in the plurality of bulkheads 120a-d in a horizontal arrangement (such as the arrangement shown in FIG. 1), screws may not be readily fastened into holes 102a-d in the brackets 104a-d of the electronic cards 101a-d to secure the electronic cards 101a-d to the card bulkheads 120a-d. As can be seen in FIG. 1, it is difficult, if not impossible to operate a screwdriver to drive a screw into the holes 102a-d in the brackets 104a-d to secure the electronic cards 101a-d to the card bulkheads 120a-d.

Instead, fasteners and fastening systems are disclosed herein which enable electronic cards to be arranged in a manner such as the arrangement shown in FIG. 1 (e.g., substantially horizontally and adjacent one another), with conventional fastening means such as screws and using a screwdriver. The fasteners and fastening systems may be used, for example, even if the bulkheads are directly adjacent another component such as another bulkhead (e.g., as bulkhead 120a is directly adjacent bulkhead 120b), or even a housing wall. The connector is still accessible (e.g., using a screwdriver) to secure the electronic card 101a-d to the bulkhead 120a.

Before continuing, it is noted that the fasteners and fastening systems described herein may be utilized with any components in any electronic devices. Use of the fasteners and fastening systems is not limited to use with PCI cards in rack environments. The rack environments and PCI cards described herein are merely intended as an illustration of one use of the fasteners and fastening systems. Other example electronic devices may also include any of a wide variety of computing systems, such as a stand-alone desktop, server, or laptop computers, workstations, or other electronic appliances, to name only a few example uses of the fastener and fastening systems described herein.

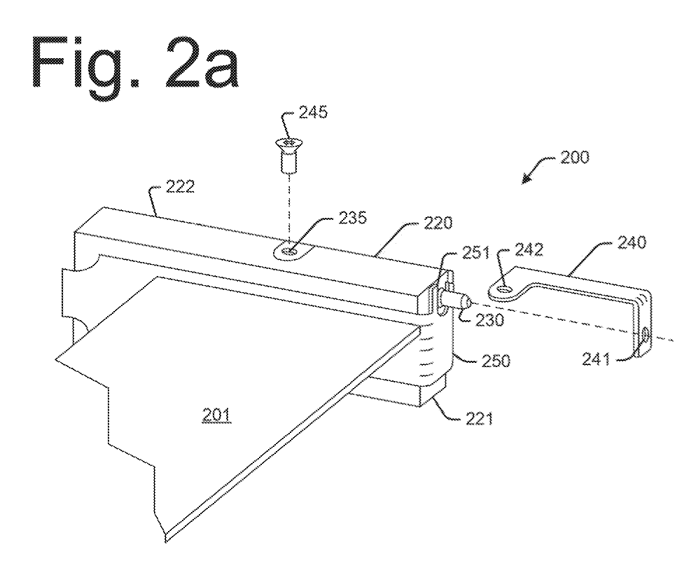

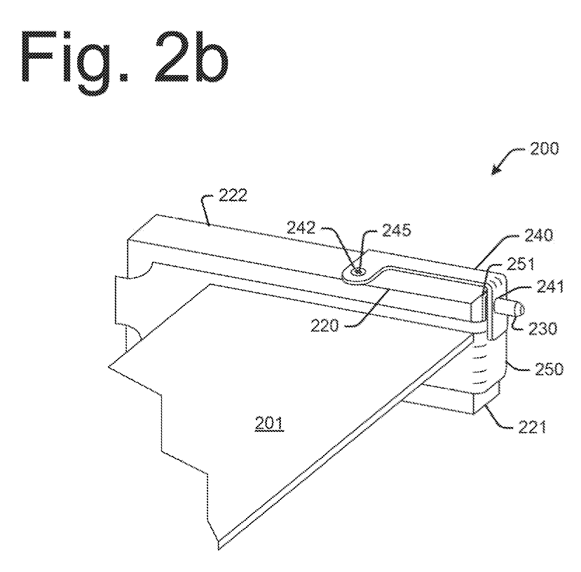

FIG. 2a is an exploded perspective view of an example fastener or fastening system 200 for connecting an electronic card 201 to a bulkhead 220. FIG. 2b is a perspective view of the fastening system in FIG. 2a showing the electronic card 201 after being connected to the bulkhead 220. In an example, a fastening system 200 for an electronic card 201 comprises a bulkhead 220 having a pin 230 extending out of a first side 221 of the bulkhead 220. An opening 235 is formed on a second side 222 of the bulkhead 220. As can be seen in FIGS. 2a-b, the first and second sides of the bulkhead 220 are arranged in a substantially perpendicular relation to each other.

The fastening system 200 also comprises a bracket 240 to hold a portion of the electronic card 201 on the pin 230 of the bulkhead 220. The portion of the electronic card 201 may be a frame assembly 250. As is convention for PCI cards, the frame assembly 250 is a substantially L-shaped bracket with a computer board attached thereto. The L-shaped bracket includes a hole or slot 251 formed therein. A screw may be inserted through the hole or slot 251 to secure the bracket to the bulkhead. However, if another bulkhead (or other component or housing wall) is directly adjacent the hole 251, then it may be difficult if not impossible to operate a screwdriver here to fasten the screw to the bulkhead.

Accordingly, the fastening system 200 described herein uses a pin 230. Pin 230 does no need to be tightened using a screwdriver to secure the frame assembly 250 of the electronic card 201 to the bulkhead 220. Instead, the frame assembly 250 of the electronic card 201 is fitted on the pin 230, and the bracket 240 fits over the pin 240 to hold the frame assembly 250 on the pin 230.

The pin 230 engages through a hole 251 formed in the frame assembly 250 of electronic card 201. The pin 230 also fits through an opening 241 formed in the bracket 240 as the bracket 240 is fitted over the pin 230 of the bulkhead 220.

The bracket 240 is substantially L-shaped and thus can be secured to the bulkhead using a connector 245 mating with the opening 235 formed on the second side 222 of the bulkhead 220. The connector 245 can be a screw or other fastening device. The opening 235 formed on the second side 222 of the bulkhead 220 may be threaded to receive the screw. The connector 245 holds the bracket 240 on the bulkhead 220, and thereby the bracket 240 secures the electronic card 201 to the bulkhead 220.

As can be seen in FIGS. 2a-b, a conventional screwdriver can be used to readily access (tighten and release) the connector 245 from above the bulkhead 220, without having to reach down the side in between the bulkheads.

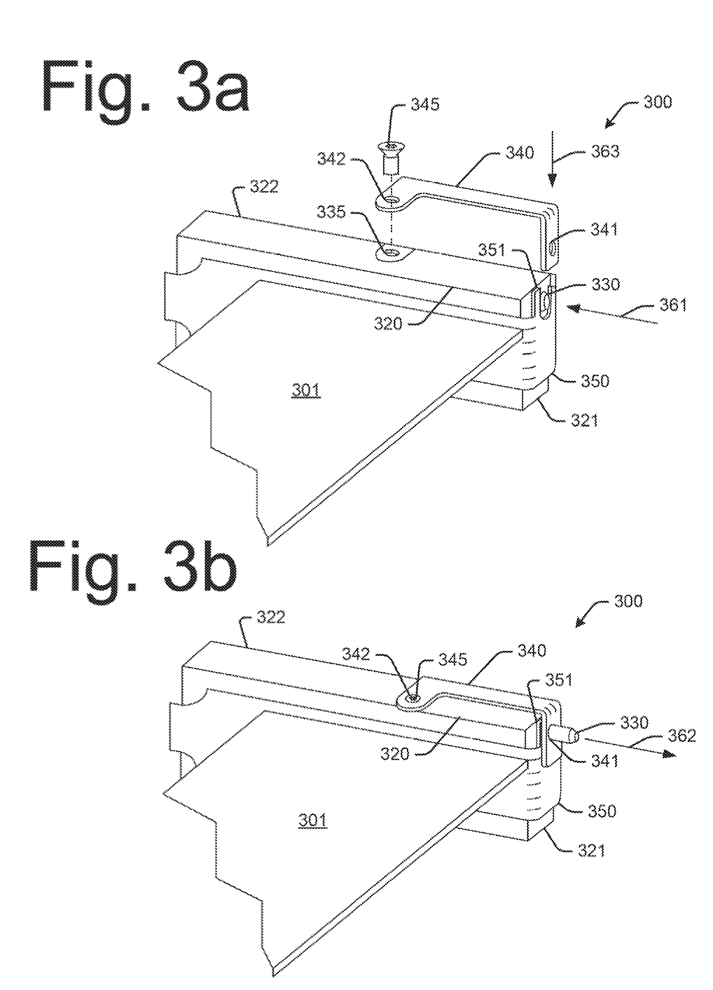

FIGS. 3a-b are perspective views of another example fastening system 300 for connecting an electronic card 301 to a bulkhead 320. It is noted that 300-series reference numbers are used in FIGS. 3a-b to correspond to similar components described above with reference to FIGS. 2a-b. Therefore, the same components are not described again for FIGS. 3a-b.

In the example shown in FIGS. 3a-b, the pin 330 is depressible (e.g., in the direction of arrow 361) at least partially into the bulkhead 330. In an example, the pin 330 is spring loaded so that the pin 330 automatically springs back (e.g., in the direction arrow 362) out of the bulkhead 320 upon release. Such a configuration may be used, for example, in particularly tight areas so that the frame assembly 350 of the electronic card 301 can be readily pressed down (in the direction of arrow 365) over the pin 330.

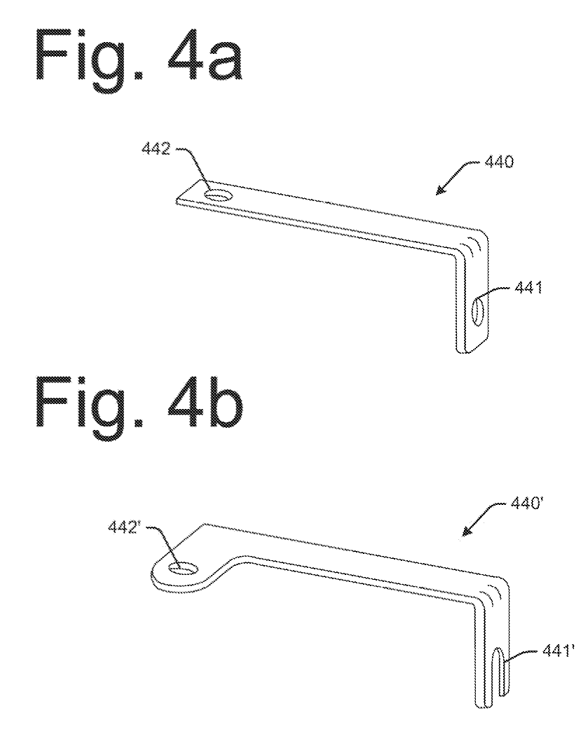

FIGS. 4a-b are perspective views of example brackets 440 and 440′ for use with a fastening system for connecting an electronic card (e.g., electronic card 201 in FIGS. 2a-b or electronic card 301 in FIGS. 3a-b) to a bulkhead. It is noted that 400-series and 400′-series reference numbers are used in FIGS. 4a-b to correspond to similar components described above with reference to FIGS. 2a-b and 3a-b. Therefore, the same components are not described again for FIGS. 4a-b.

In the example shown in FIG. 4a, the openings 441 and 442 formed in the bracket 440 are holes. In addition, the holes 441 and 442 are formed on the bracket 440 substantially along the same central axis as the bracket 440 (e.g., as compared to the offset configuration on the bracket 240 shown in FIGS. 2a and 2b).

In FIG. 4b, the opening 441 formed in the bracket 440 is a slot. The slot shown in FIG. 4b may be used, for example, in particularly tight areas so that the frame assembly of the electronic card can be readily pressed over the pin (e.g., pin 230 in FIGS. 2a-b and pin 330 in FIGS. 3a-b).

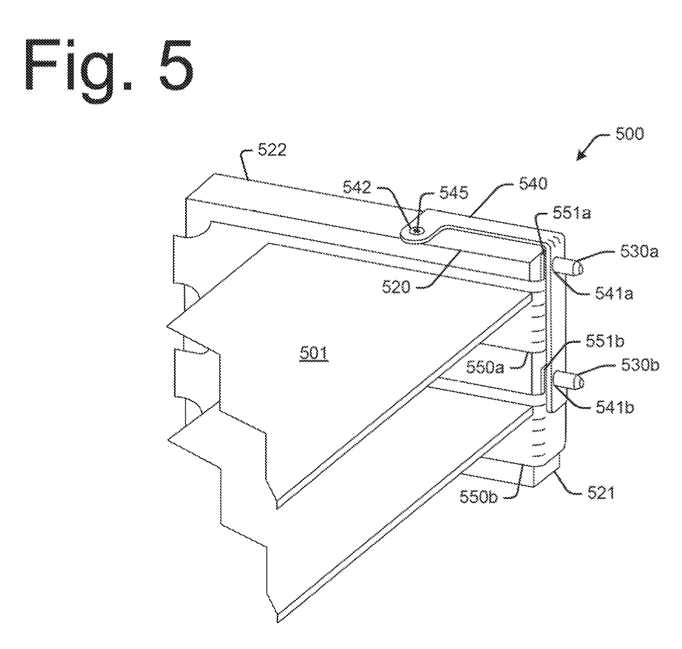

FIG. 5 is a perspective view of another example fastening system 500 for connecting a plurality of electronic cards 501a and 501e to a bulkhead 520. It is noted that 500-series reference numbers are used in FIG. 5 to correspond to similar components described above with reference to FIGS. 2a-b and 3a-b. Therefore, the same components are not described again for FIG. 5.

In the example shown in FIG. 5, the bulkhead 520 further comprises a plurality of pins 530a-b extending out of the first side 521 of the bulkhead 520 to secure a plurality of electronic cards 501a and 501e in substantially parallel relation to, one another. Accordingly, the fastening system 500 includes a bracket 540 that can be used to hold a plurality of electronic cards 501a and 501e on the bulkhead in substantially parallel relation to one another, even if the first side 521 would be otherwise inaccessible using a screwdriver.

It is noted that the examples shown and described are provided for purposes of illustration and are not intended to be limiting. Still other examples are also contemplated.

1. A fastening system for an electronic card, comprising:
a bulkhead having a pin extending out of a first side of the bulkhead and an opening formed on a second side of the bulkhead, the first and second sides of the bulkhead arranged in a substantially perpendicular relation to each other;
a bracket to hold a portion of the electronic card on the pin of the bulkhead; and
a connector mating with the opening formed on the second side of the bulkhead, the connector to hold the bracket on the bulkhead and thereby the bracket secures the electronic card to the bulkhead.

2. The fastening system of claim 1, wherein the first side of the bulkhead is positionable adjacent another bulkhead or housing wall while leaving the connector accessible to secure the electronic card to the bulkhead.

3. The fastening system of claim 1, wherein the connector is accessible to secure the electronic card to the bulkhead even when the first side of the bulkhead is inaccessible.

4. The fastening system of claim 1, wherein the pin is depressible at least partially into the bulkhead and automatically springs back out of the bulkhead upon release.

5. The fastening system of claim 1, wherein the pin engages a hole formed in a frame assembly of the electronic card.

6. The fastening system of claim 1, wherein the pin engages a slot formed in a frame assembly of the electronic card.

7. The fastening system of claim 1, wherein the bracket is substantially L-shaped.

8. The fastening system of claim 1, wherein the connector is a screw and the opening formed on the second side of the bulkhead is threaded to receive the screw.

9. The fastening system of claim 1, further comprising an opening formed in the bracket to fit over the pin of the bulkhead.

10. The fastening system of claim 1, wherein the opening formed in the bracket is a hole.

11. The fastening system of claim 1, wherein the opening formed in the bracket is a slot.

12. The fastening system of claim 1, further comprising a plurality of pins pin extending out of a first side of the bulkhead to secure a plurality of electronic cards in substantially parallel relation to one another.

13. The fastening system of claim 1, wherein the bracket holds a plurality of electronic cards on the bulkhead in substantially parallel relation to one another.

14. The fastening system of claim 1. wherein the connector is accessible in a vertical orientation even when the electronic card is in a horizontal orientation.

15. A fastener for holding an electronic card on a bulkhead, comprising:
a pin on a first side of the bulkhead;
a bracket to hold a portion of the electronic card on the pin of the bulkhead; and
a connector to hold the bracket on a second side of the bulkhead, the first side of the bulkhead substantially perpendicular to the second side of the bulkhead.

16. The fastener of claim 15, wherein the connector is accessible to secure the electronic card to the bulkhead even when the first side of the bulkhead is inaccessible.

17. The fastener of claim 15, wherein the pin fits around both an opening formed in a frame assembly of the electronic card and an opening formed in the bracket.

18. The fastener of claim 15, wherein the bracket is substantially L-shaped to simultaneously engage both the first side of the bulkhead and the substantially perpendicular second side of the bulkhead.

19. The fastener of claim 15, wherein the bracket holds a plurality of electronic cards on the bulkhead in a substantially stacked relation to one another.

20. The fastener of claim 15, wherein the connector is accessible in a vertical orientation even when the electronic card is in a horizontal orientation.
